(19) United States
(12) Patent Application Publication
(10) Pub. No.: US 2016/0054360 A1
(43) Pub. Date: Feb. 25, 2016

(54) CURRENT MEASUREMENT APPARATUS, DEVICE-BEHAVIOR DETECTION SYSTEM, CURRENT MEASUREMENT METHOD, AND PROGRAM

(71) Applicant: MITSUBISHI ELECTRIC CORPORATION, Tokyo (JP)

(72) Inventor: Toshiyasu HIGUMA, Tokyo (JP)

(21) Appl. No.: 14/781,325

(22) PCT Filed: Apr. 16, 2014
(86) PCT No.: PCT/JP2014/060807

§ 371 Date: Sep. 30, 2015

(30) Foreign Application Priority Data
Apr. 19, 2013 (JP) 2013-088166

(51) Int. Cl. G01R 15/18; G01R 19/00

(52) U.S. Cl. CPC G01R 15/183; G01R 19/0092

(57) ABSTRACT

The current measurement apparatus measures the current flowing through a power cable that connects electrical equipment to an AC power source that supplies power to the electrical equipment. Said current measurement apparatus is provided with the following: a sensor that sandwiches the power cable and detects the common mode current flowing therein; a determiner that acquires current information indicating change in the detected common mode current; and a transmitter that transmits the acquired current information to a control apparatus that detects the operating state of the electrical equipment.

### TECHNICAL FIELD

This disclosure relates to a current measurement apparatus, a device-behavior detection system, current measurement method and a program for measuring electric current flowing through a power cable that connects electrical equipment to a power source that supplies power to that electrical equipment.

### BACKGROUND ART

Conventionally, technology has been disclosed of methods for measuring the amount of power consumed by electrical equipment; for example, Patent Literature 1 discloses technology in which a current measurement device, that measures electric current supplied from a power source to electrical equipment that is connected to a power outlet, is provided in each of the power outlets of a power strip.

### CITATION LIST

### Patent Literature

Patent Literature 1: Unexamined Japanese Patent Application Kokai Publication No. 2011-159464

### SUMMARY OF INVENTION

### Technical Problem

However, in the technology disclosed in Patent Literature 1, even though most suitable for the case of measuring the power consumption of electrical equipment such as an air conditioner or a refrigerator that is always connected to the same power outlet, in the case of electrical equipment such as a vacuum cleaner that is used by temporarily connecting to power outlets in various rooms, it is necessary to newly attach the current measurement device to the power outlet where the electrical equipment will be connected, which takes time.

Taking the situation described above into consideration, the objective of the present disclosure is to provide a current measurement apparatus, device-behavior detection system, current measurement method and program that are capable of easily measuring electric current that is supplied from a power source to electrical equipment.

### Solution to Problem

In order to accomplish the objective above, the current measurement apparatus of this disclosure measures current flowing through a power cable that connects electrical equipment to a power source that supplies power to that electrical equipment. This current measurement apparatus comprises a first body, a second body and a sensor. The power cable is held between the first body and the second body. The sensor is provided in at least one of the first body and the second body, and detects the current flowing through the power cable.

### Advantageous Effects of Invention

According to the present disclosure, current flowing through a power cable is detected by a sensor that is provided in at least one of a first body and a second body that holds a power cable in between, so it is possible to easily measure the current supplied to electrical equipment from a power source.

### BRIEF DESCRIPTION OF DRAWINGS

FIG. 1 is a block diagram illustrating the schematic construction of a device-behavior detection system of a first embodiment;

FIG. 2A is a schematic perspective view of a current measurement apparatus of a first embodiment after assembly;

FIG. 2B is a schematic perspective view of a current measurement apparatus of a first embodiment before assembly;

FIG. 3 is a block diagram illustrating an example of the schematic construction of a current measurement apparatus of a first embodiment;

FIG. 4 is a block diagram illustrating the hardware construction of a control apparatus of a first embodiment;

FIG. 5 is a schematic block diagram illustrating the functional construction of a controller of the control apparatus of a first embodiment;

FIG. 6 is a flowchart illustrating an example of the flow of a current measurement process;

FIG. 7 is a flowchart illustrating an example of the flow of an operation information acquisition process;

FIG. 8A illustrates transition over time of the common mode current value that is acquired by the current value acquirer of the current measurement apparatus of a first embodiment;

FIG. 8B illustrates the transition over time of current information that is acquired by a determiner of the current measurement apparatus of a first embodiment;

FIG. 8C illustrates the transition over time of operation information that is acquired by an operation information acquirer of the control apparatus of a first embodiment;

FIG. 9A illustrates transition over time of the common mode current value that is acquired by the current value acquirer of the current measurement apparatus of a second embodiment;

FIG. 9B illustrates the transition over time of current information that is acquired by a determiner of the current measurement apparatus of a second embodiment;

FIG. 9C illustrates the transition over time of operation information that is acquired by an operation information acquirer of the control apparatus;

FIG. 10A is a schematic perspective view of a current measurement apparatus of a fourth embodiment;

FIG. 10B is a cross-sectional view illustrating section A-A in FIG. 10A;

FIG. 11 is a block diagram illustrating an example of the schematic construction of the current measurement apparatus of a fourth embodiment;

FIG. 12A illustrates an example of a circuit diagram for the current measurement apparatus of an eighth embodiment; and

FIG. 12B illustrates an example of a circuit diagram for the current measurement apparatus of an eighth embodiment.

### DESCRIPTION OF EMBODIMENTS

In the following, embodiments of the present disclosure will be explained in detail with reference to the accompanying drawings.

### First Embodiment

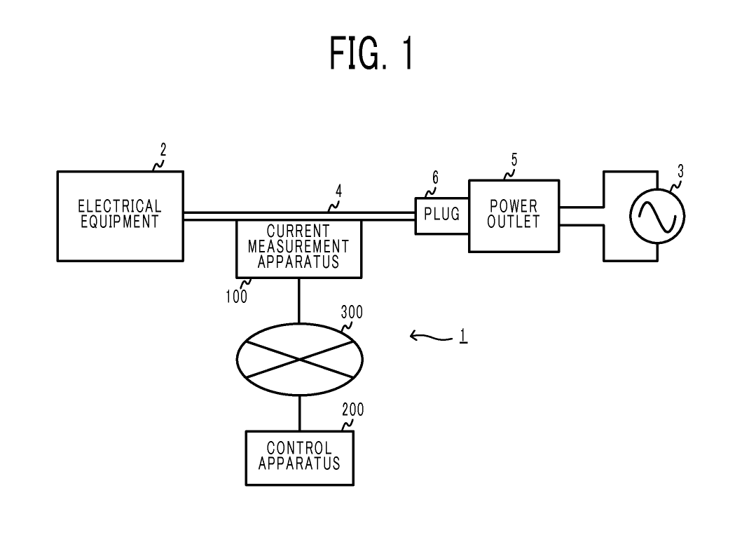

FIG. 1 illustrates the overall construction of a device-behavior detection system 1 of a first embodiment of the present disclosure. As illustrated in FIG. 1, the device-behavior detection system 1 comprises a current measurement apparatus 100, a control apparatus 200, and a network 300. The current measurement apparatus 100 is communicatively connected to the control apparatus 200 by way of the network 300.

The current measurement apparatus 100 is an apparatus that measures the electric current flowing through a power cable 4 that connects electrical equipment 2 to an AC power source 3. The current measurement apparatus 100 that will be explained later, is provided on the power cable 4. The current measurement apparatus 100 transmits current information that indicates the measured current to the control apparatus 200 by way of the network 300.

The electrical equipment 2 is a device that operates with electric current that is supplied from the AC power source 3. The electrical equipment 2 can receive the supply of power from the AC power source 3 by a plug 6 that is provided on one end of the power cable 4 being connected to a power outlet 5 that is connected to the AC power source 3.

The control apparatus 200 detects the operation of the electrical equipment 2 based on current information that is acquired from the current measurement apparatus 100.

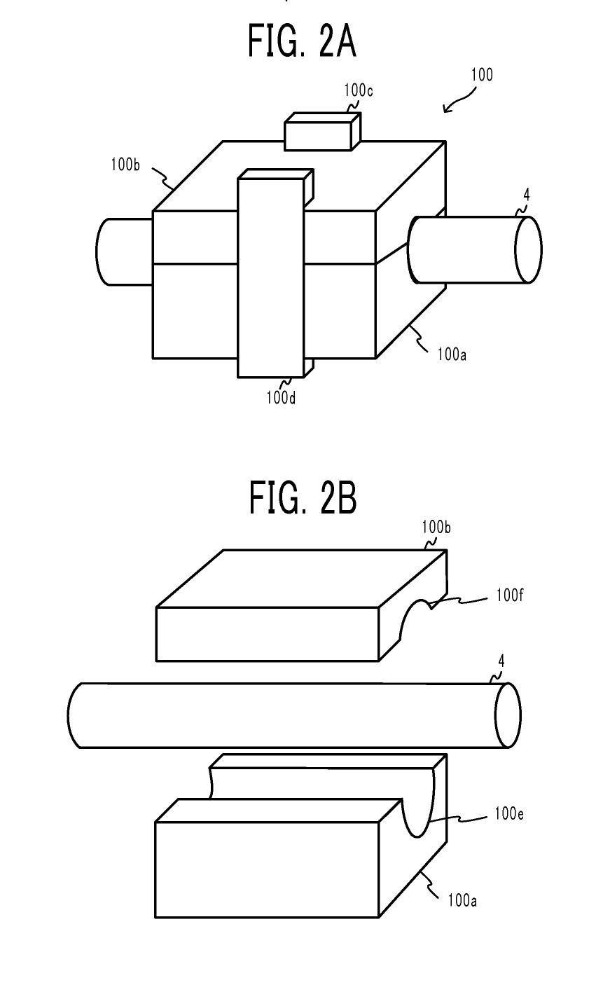

Next, the external appearance of the current measurement apparatus 100 will be explained. FIG. 2A and FIG. 2B are schematic perspective views illustrating the current measurement apparatus 100. As illustrated in FIG. 2A, the current measurement apparatus 100 comprises a first body 100a, a second body 100b, and clamps 100c, 100d. As illustrated in FIG. 2B, the first body 100a and the second body 100b have concave sections 100e, 100f that have the same shape as part of the outer circumferential shape of the cross section of the power cable 4. The current measurement apparatus 100 is provided on the power cable 4 by the first body 100a and the second body 100b being placed together so that the power cable 4 is embedded between the concave sections 100e, 100f, and by the clamps 100c, 100d being clamping together the first body 100a and the second body 100b.

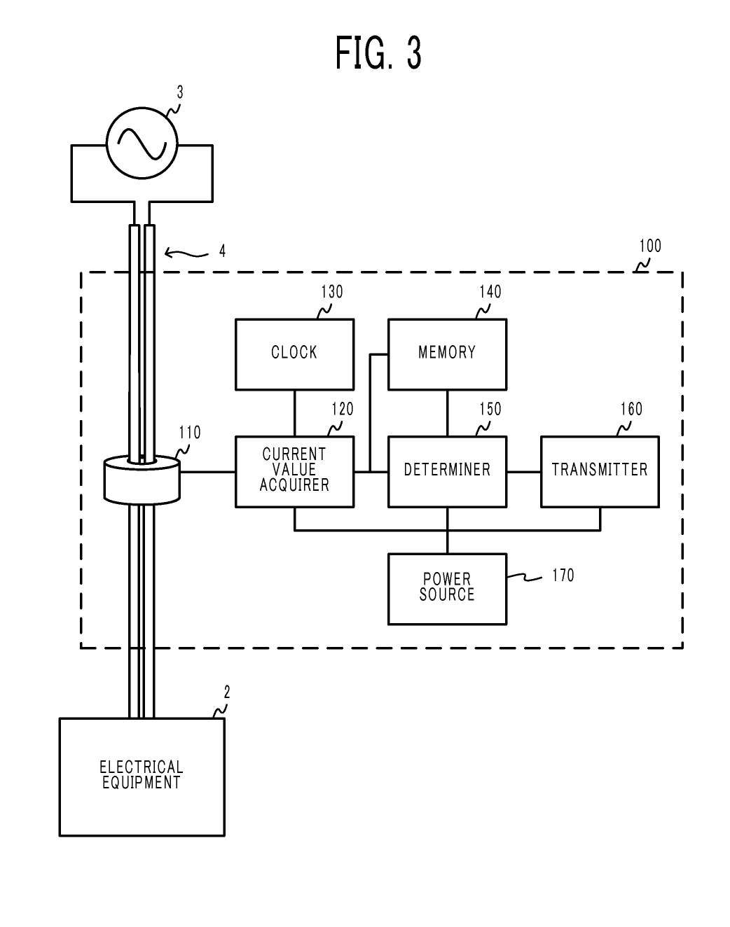

Next, the construction of the current measurement apparatus 100 will be explained. FIG. 3 illustrates an example of the schematic construction of the current measurement apparatus 100 of this embodiment. As illustrated in FIG. 3, the current measurement apparatus 100 comprises a sensor 110, a current value acquirer 120, a clock 130, a memory 140, a determiner 150, a transmitter 160 and a power source 170. The sensor 110, the current value acquirer 120, the clock 130, the memory 140, the determiner 150, the transmitter 160 and the power source 170 that make up the hardware are housed in at least one of the first body 100a and second body 100b.

The sensor 110 detects the common mode current flowing through the power cable 4. The common mode current is noise current that is generated by unbalanced current flowing through the two conducting wires of the power cable 4. More specifically, the sensor 110 comprises a current transformer (CT) that is formed by winding conducting wires around a ferromagnetic ring-shaped core.

The current value acquirer 120 acquires a signal that indicates the value of the current that is detected by the sensor 110. The current value acquirer 120 records the acquired current value in the memory 140 in association with the present time that is acquired from the clock 130.

The clock 130 comprises a timer that clocks the present time.

The memory 140 comprises a recording medium such as a non-volatile semiconductor memory, and stores a current value signal that is acquired by the current value acquirer 120. Moreover, the memory 140 stores a threshold value that is used when determining changes in the current value. This threshold value, for example, is set beforehand by a user, and recorded in the memory 140.

The determiner 150, based on the current value signal that is stored in the memory 140, determines for each pre-determined interval (judgment period) whether the current value that is detected by the sensor 110 has increased, decreased or is unchanged. More specifically, the determiner 150 determines that the current value has increased when the amount of increase in the current value during the most recent judgment period is greater than a threshold value. Moreover, the determiner 150 determines that the current value has decreased when the amount of decrease in the current value during the most recent judgment period is greater than a threshold value. When the determiner 150 determines that the current value has not increased or decreased, the determiner 150 determines that the current value is unchanged.

When the determiner 150 determines that the current value has increased, the determiner 150 outputs “1”, for example, as current information indicating that the current value has increased. Moreover, when the determiner 150 determines that the current value has decreased, the determiner 150 outputs “−1”, for example, as current information indicating that the current value has decreased. When the determiner 150 determines that the current value is unchanged, the determiner 150 outputs “0”, for example, as current information indicating that the current value is unchanged.

The transmitter 160 comprises an interface for communication with the network 300, and transmits the current information outputted by the determiner 150 to the control apparatus 200 by way of the network 300.

The power source 170, for example, comprises a battery such as a button battery or the like, and supplies power to each of the components of the current measurement apparatus 100.

Furthermore, by the CPU (Central Processing Unit) of the current measurement apparatus 100 executing a control program that is recorded in the memory 140, for example, the current measurement apparatus 100 of this embodiment functions as the current value acquirer 120 and the determiner 150 described above. However, the hardware construction of the current measurement apparatus 100 is not limited to this, and for example, the current value acquirer 120 and/or the determiner 150 can be constructed using dedicated circuits or DSP (Digital Signal Processor), and the processing thereof can be performed by a dedicated hardware instead of being performed by a control program.

Next, the construction of the control apparatus 200 of this embodiment will be explained in detail.

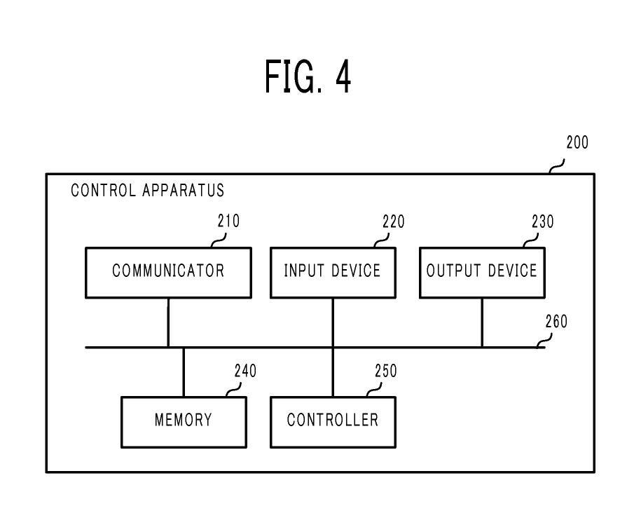

FIG. 4 illustrates an example of the hardware of the control apparatus 200 of this embodiment. As illustrated in FIG. 4, the control apparatus 200 comprises a communicator 210, an input device 220, an output device 230, a memory 240, and a controller 250, and the components are connected by way of a bus 260.

The communicator 210 comprises an interface for conducting wireless or wired communication with the current measurement apparatus 100 by way of the network 300.

The input device 220 comprises an input apparatus such as buttons, touch panel, keyboard and the like. The input device 220 receives operation input from a user and outputs an operation input signal that corresponds to the received operation input to the controller 250.

The output device 230 comprises a display apparatus such as a CRT (Cathode Ray Tube) or liquid crystal display, and displays data such as text, images and the like that are supplied from the controller 250.

The memory 240 comprises a writable storage device such as a hard disk drive, flash memory or SSD (Solid State Drive).

The controller 250, for example, comprises a CPU, ROM (Read Only Memory) that stores a program that the CPU executes, RAM (Random Access Memory) that temporarily stores data that the CPU generates, and a timer that clocks the present time, and performs overall control of the control apparatus 200.

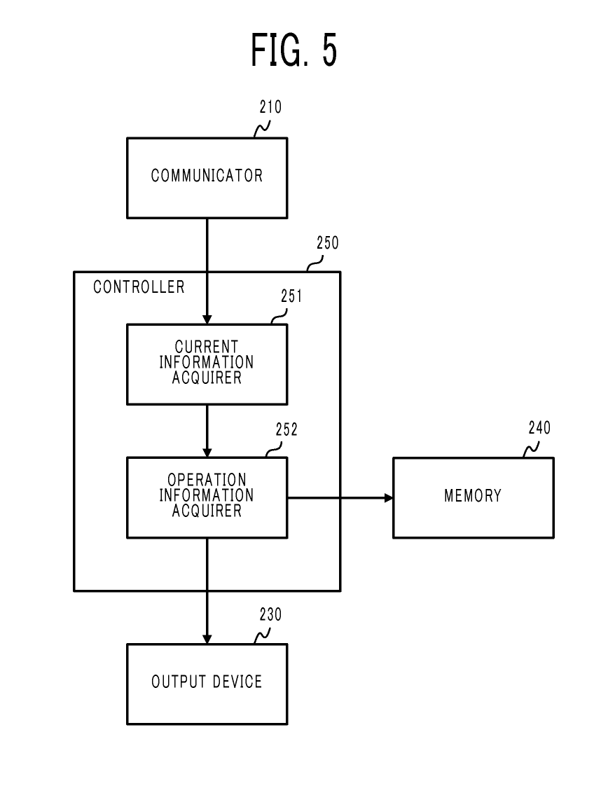

FIG. 5 is a block diagram that illustrates an example of the functional construction of the controller 250. As illustrated in FIG. 5, the controller 250 functions as a current information acquirer 251, and an operation information acquirer 252.

The current information acquirer 251 acquires current information from the current measurement apparatus 100 by way of the communicator 210. The current information that is acquired by the current information acquirer 251 is stored in RAM, for example.

The operation information acquirer 252 acquires operation information that indicates the operating state of the electrical equipment 2 based on the current information that is acquired by the current information acquirer 251.

More specifically, the operation information acquirer 252, based on the current information that is acquired by the current information acquirer 251, acquires information that indicates change over time of the operating state of the electrical equipment 2. Here, as the operating state of the electrical equipment 2, the operation information acquirer 252 acquires either the state in which the power source is ON and the electrical equipment 2 is operating (ON state), or the state in which the power source is OFF and the electrical equipment 2 is not operating (OFF state). Moreover, the operation information acquirer 252 records the acquired operating state in the memory 240. The operation information acquirer 252 may also output the acquired operating state to the output device 230.

Next, the operation of the current measurement apparatus 100 of this embodiment will be explained.

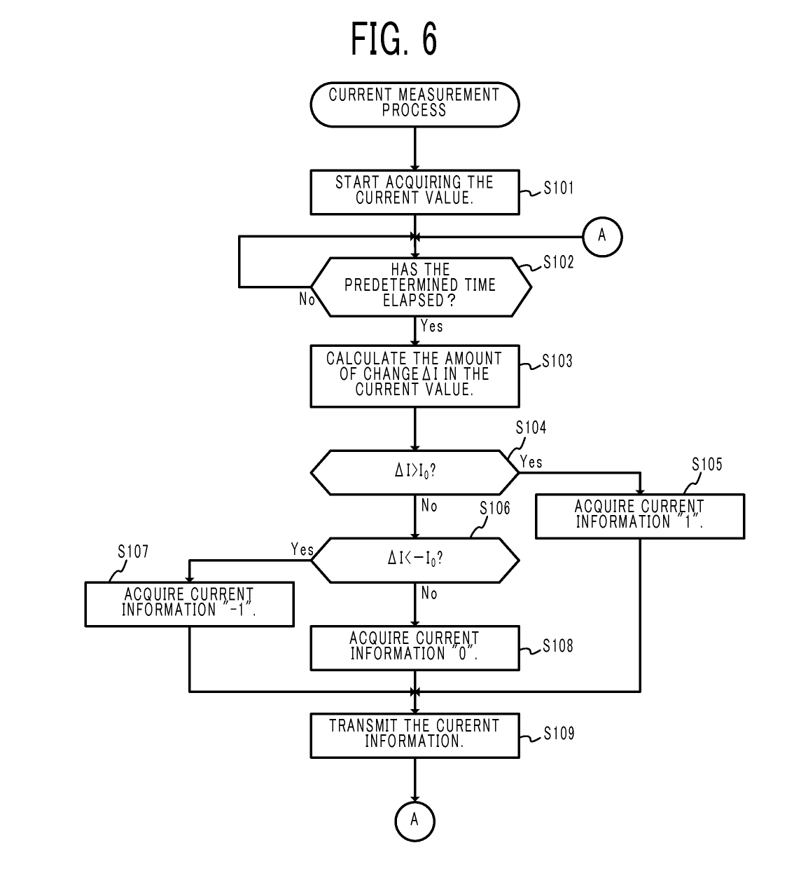

FIG. 6 illustrates an example of a flowchart of a current measurement process that the current measurement apparatus 100 executes. This process starts by the user turning ON the power of the current measurement apparatus 100.

The current value acquirer 120 starts acquiring the current value of the common mode current flowing through the power cable 4 during a predetermined sampling period from the sensor 110 (step S101). Then, the current value acquirer 120 records the acquired current value in the memory 140.

Next, the determiner 150 determines whether or not the judgment period (for example, 10 seconds) has elapsed (step S102). When it is determined that the judgment period has not elapsed (step S102; NO), the determiner 150 turns into a waiting state until it is determined that the judgment period has elapsed.

When it is determined that the judgment period has elapsed (step S102; YES), the determiner 150 calculates the amount of change ΔI in the current value during the most recent judgment period from among the current values stored in the memory 140 (step S103).

Next, the determiner 150 determines whether or not the amount of change ΔI that is calculated in step S103 is greater than a threshold value I₀ (I₀>0) (step S104).

When it is determined that the amount of change ΔI is greater than the threshold value I₀ (step S104; YES), the determiner 150 acquires “1” as current information that indicates that the current value has increased (step S105).

When it is determined that the amount of change ΔI is not greater than the threshold value I₀ (step S104; NO), the determiner 150 determines whether or not the amount of change ΔI calculated in step S103 is less than the threshold value −I₀ (step S106).

When it is determined that the amount of change ΔI is less than the threshold value −I₀ (step S106; YES), the determiner 150 acquires “−1” as current information that indicates that the current value has decreased (step S107).

When it is determined that the amount of change ΔI is not less than the threshold value −I₀ (step S106; NO), the determiner 150 acquires “0” as the current information that indicates that the current value is unchanged (step S108).

Next, the transmitter 160 transmits the current information that is acquired by the determiner 150 to the control apparatus 200 (step S109). Then, processing returns to step S102.

The current measurement apparatus 100 then repeats steps S102 to S109, until, for example, the user turns OFF the power of the current measurement apparatus 100.

Next, the operation of the control apparatus 200 of this embodiment will be explained.

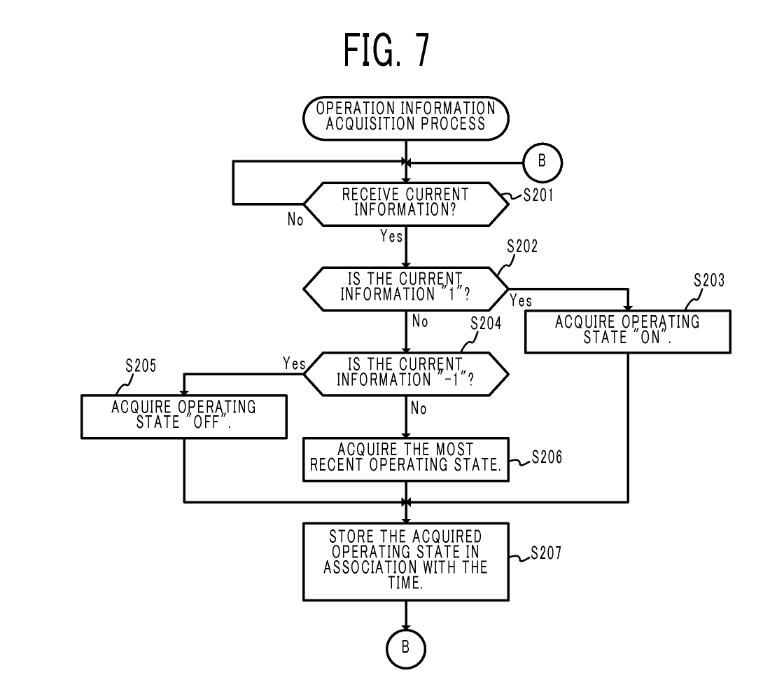

FIG. 7 illustrates an example of a flowchart of an operation information acquisition process that the control apparatus 200 executes. This process is started by, for example, receiving operation input that indicates the start of the operation information acquisition process by the user by way of the input device 220.

The current information acquirer 251 determines whether or not current information has been received from the current measurement apparatus 100 by way of the communicator 210 (step S201). When it is determined that current information has not been received (step S201; NO), the current information acquirer 251 turns into a waiting state until current information is received.

When it is determined that the current information acquirer 251 has acquired current information (step S201; YES), the operation information acquirer 252 determines whether or not the received current information indicates “1” (step S202).

When it is determined that the received current information indicates “1” (step S202: YES), the operation information acquirer 252 acquires “ON” as the operating state (step S203).

When it is determined that the received current information does not indicate “1” (step S202: NO), the operation information acquirer 252 determines whether or not the received current information indicates “−1” (step S204).

When it is determined that the received current information indicates “−1” (step S204: YES), the operation information acquirer 252 acquires “OFF” as the operating state (step S205).

When it is determined that the received current information does not indicate “−1” (step S204: NO), the operation information acquirer 252 acquires the most recent operating state that is stored in the memory 240 as the operating state (step S206).

Next, the operation information acquirer 252 stores the acquired operating state in association with the time when the current information has been received in the memory 240 (step S207). Processing then returns to step S201.

The control apparatus 200 then repeats the processing of steps S201 to S207 until, for example, receiving operating input indicating the end of the operation information acquisition process by the user by way of the input device 220.

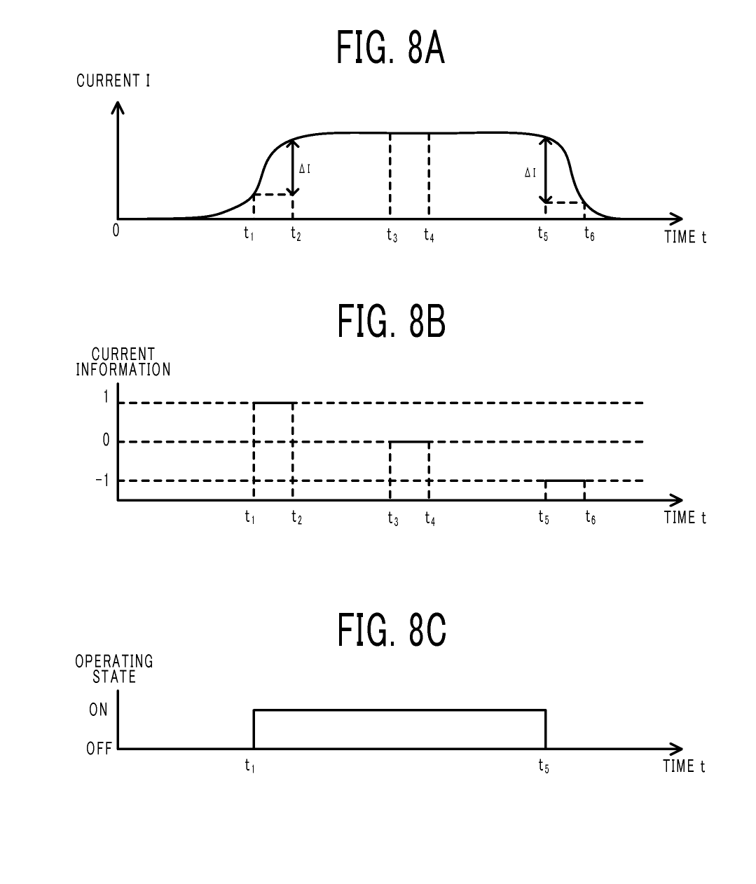

Next, an example of the current information that is acquired by the current measurement process, and the operation information that is acquired by the operation information acquisition process described above will be explained in detail. FIG. 8A illustrates the transition over time of the common mode current value that is acquired by the current value acquirer 120 of the current measurement apparatus 100, FIG. 8B illustrates the transition over time of the current information that is acquired by the determiner 150 of the current measurement apparatus 100, and FIG. 8C illustrates the transition over time of the operation information that is acquired by the operation information acquirer 252 of the control apparatus 200. In the explanation below, the current measurement process is presumed to start at time t=0.

First, when it is determined that the amount of change ΔI in the current value of the common mode current between time t₁ and time t₂ is greater than a threshold value I₀, “1” is acquired as the current information. Then, “ON” is acquired as the operating state.

Next, when it is determined that the amount of change ΔI in the current value of the common mode current between time t₃ and t₄ is −I₀<ΔI <I₀, “0” is acquired as the current information. Then, the operating state “ON” that is acquired between time t₁ and time t₂ as the most recent operation information is acquired as the operating state between time t₃ and time t₄.

Then, when it is determined that the amount of change ΔI in the current value of the common mode current between time t₅ and t₆ is less than a threshold value −I₀, “−1” is acquired as the current information. Then, “OFF” is acquired as the operating state.

As explained above, in the device-behavior detection system 1 of this embodiment, the current measurement apparatus 100 that measures the current that is supplied to the electrical equipment 2 is provided on the power cable 4 of the electrical equipment 2. Therefore, even when the power outlet 5 to which the electrical equipment 2 is connected is changed, there is no need to reattach the current measurement apparatus 100 following that change, so it is possible to easily measure the value of the current that is supplied to the electrical equipment 2 without any trouble. It is also possible to acquire the operating state of the electrical equipment 2 based on the current value of the common mode current that is flowing through the power cable 4 measured by the current measurement apparatus 100.

### Second Embodiment

In the device-behavior detection system 1 of the first embodiment of this disclosure, the current measurement apparatus 100 determines whether the current value that is detected by the sensor 110 increased, decreased or unchanged for each judgment period, based on the current value signal stored in memory 140, and transmits the current information that is the judgement results to the control apparatus 200. However, the timing for the current measurement apparatus 100 to transmit the current information is not limited to this. In this second embodiment, an example will be explained in which the current measurement apparatus 100 transmits current information to the control apparatus 200 when the current value that is detected by the sensor 110 changes. The same reference numbers will be used for construction that are the same as that in the first embodiment, and the detailed explanation thereof will be omitted.

The determiner 150 of the current measurement apparatus 100 of this second embodiment determines whether or not the current value that is detected by the sensor 110 has changed for each judgment period, based on the current value signal stored in the memory 140. More specifically, the determiner 150 determines that the current value has increased when the amount of increase in the current value during the most recent judgment period is greater than a threshold value. Moreover, the determiner 150 determines that the current value has decreased when the amount of decrease in the current value during the most recent judgment period is greater than a threshold value. When the current value does not increase or decrease, the determiner 150 determines that the current value is unchanged.

Moreover, when it is determined that the current value has increased, the determiner 150 outputs “1”, for example, as current information that indicates that the current value has increased. When it is determined that the current value has decreased, the determiner 150 outputs “−1”, for example, as current information that indicates that the current value has decreased. The transmitter 160 transmits the current information that is outputted by the determiner 150 to the control apparatus 200. Moreover, when the determiner 150 determines that the current value is unchanged, the transmitter 160 does not transmit the current information to the control apparatus 200.

The operation information acquirer 252 of the control apparatus 200 of this second embodiment acquires operation information that indicates the operating state of the electrical equipment 2, based on the current information that is acquired by the current information acquirer 251. More specifically, when the current information that is acquired by the current information acquirer 251 indicates “1”, the operation information acquirer 252 acquires the change in the operating state of the electrical equipment 2 from “OFF” to “ON” as the operation information. Moreover, when the current information that is acquired by the current information acquirer 251 indicates “−1”, the operation information acquirer 252 acquires the change in the operating state of the electrical equipment 2 from “ON” to “OFF” as the operation information.

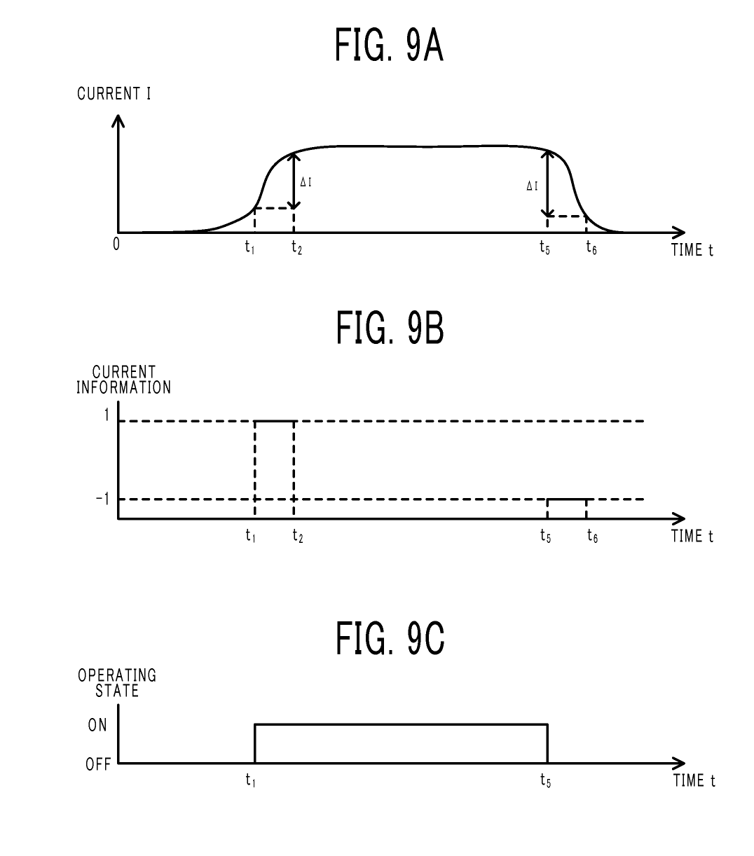

Next, an example of current information and operation information that is obtained in this second embodiment will be explained in detail. FIG. 9A illustrates the transition over time of the common mode current value that is acquired by the current value acquirer 120 of the current measurement apparatus 100, FIG. 9B illustrates the transition over time of the current information that is acquired by the determiner 150 of the current measurement apparatus 100, and FIG. 9C illustrates the transition over time of the operation information that is acquired by the operation information acquirer 252 of the control apparatus 200. In the explanation below, the current measurement process is presumed to start at time t=0.

First, when it is determined that the amount of change ΔI in the current value of the common mode current between time t₁ and time t₂ is greater than a threshold value I₀, “1” is acquired as the current information. Moreover, a change from “OFF” to “ON” at the time t₁ is acquired as the operating state.

The amount of change ΔI in the current value of the common mode current between time t₂ and t₃ is −I₀<ΔI<I₀, and the current value is determined to be unchanged. Therefore, current information is not acquired during this period, and the operating state is unchanged, or in other words, remains “ON”.

When it is determined that the change ΔI in the current value of the common mode current between time t₃ and time t₄ is less than the threshold value −I₀, “−1” is acquired as the current information. Then, the change from “ON” to “OFF” at the time t₃ is acquired as the operating state.

As explained above, in the device-behavior detection system 1 of this second embodiment, when it is determined that the current value of the measured common mode current has changed, the current measurement apparatus 100 transmits current information to the control apparatus 200. In this case as well as in the first embodiment, it is possible to acquire the operating state of the electrical equipment 2.

### Third Embodiment

In the device-behavior detection system 1 of the first embodiment of this disclosure, the current measurement apparatus 100 transmits current information to the control apparatus 200 that indicates “1”, “0” or “−1” for each judgment period, based on the change in the current value signal that is stored in the memory 140. However, the information showed by the current information that the current measurement apparatus 100 transmits is not limited to this. For example, the current measurement apparatus 100 can transmit to the control apparatus 200 the current information that shows the current waveform, or in other words, the current information shows the measured current value.

More specifically, the determiner 150 of the current measurement apparatus 100 determines whether or not the current value that is detected by the sensor 110 has changed for each judgment period, based on a current value signal that is stored in the memory 140. When it is determined that the current value has changed, the determiner 150 outputs current information that indicates the transition over time of the current value at the time when the current value has been determined to be changed. The transmitter 160 then transmits the current information that is outputted by the determiner 150 to the control apparatus 200.

Moreover, the operation information acquirer 252 of the control apparatus 200 acquires operation information that indicates the operating state of the electrical equipment 2, based on the current information that is acquired by the current information acquirer 251. More specifically, the operation information acquirer 252 acquires the operating state of the electrical equipment 2 by analyzing the transition over time of the current value indicated by the current information that is acquired by the current information acquirer 251. For example, the memory 240 stores in advance information that indicates the transition over time of the current value when the operating state changed from “OFF” to “ON”, and the transition over time of the current value when the operating state changed from “ON” to “OFF”, and the operation information acquirer 252 acquires the operating state of the electrical equipment 2 by comparing the transition over time of the current value indicated by the current information that is acquired by the current information acquirer 251 with the information indicating the transition over time of the current value that is stored in the memory 240.

As explained above, in the device-behavior detection system 1 of this third embodiment, the current measurement apparatus 100 transmits current information to the control apparatus 200 indicating the transition over time of the changed current value when it is determined that the measured current value of the common mode current has changed. In this case as well as in the first embodiment, it is possible to acquire the operating state of the electrical equipment 2.

### Fourth Embodiment

In the device-behavior detection system 1 of the first embodiment of this disclosure, the current measurement apparatus 100 measured the current value of the common mode current flowing through the power cable 4, however, the current that is measured by the current measurement apparatus 100 is not limited to this. In a fourth embodiment, an example is explained in which the current measurement apparatus 100 measures the current value of current that is flowing through one of the conducting wires of a power cable 4 that includes two conducting wires. The same reference numbers are used for construction that are the same as in the first embodiment, and a detailed explanation thereof will be omitted.

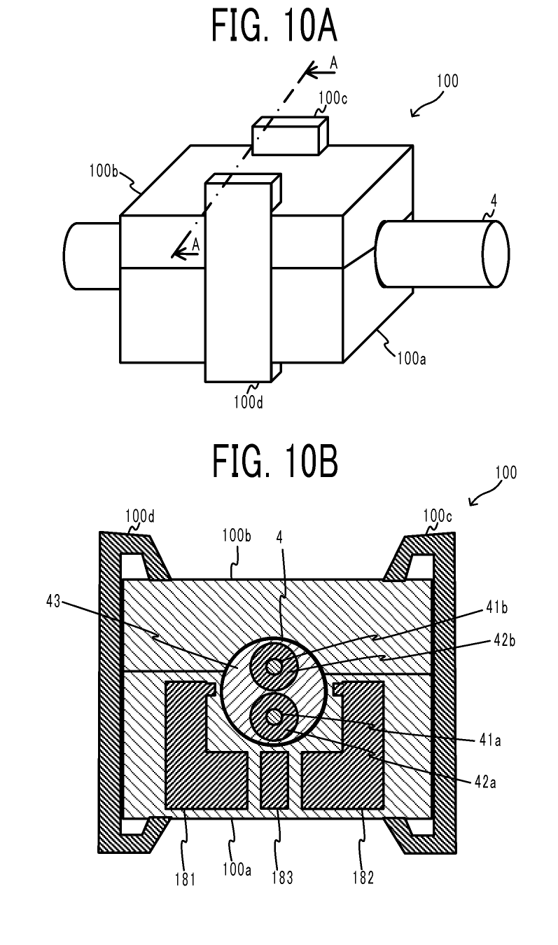

The construction of the current measurement apparatus 100 of this fourth embodiment will be explained. FIG. 10A is an schematic perspective view of the current measurement apparatus 100, and FIG. 10B is a cross-sectional view of section A-A in FIG. 10A. As illustrated in FIG. 10A, the current measurement apparatus 100 comprises a first body 100a, a second body 100b, and clamps 100c, 100d, as in the first embodiment. Moreover, as illustrated in FIG. 10B, the first body 100a comprises magnetic cores 181, 182, and a magnetic flux detector 183.

The magnetic cores 181, 182 are nearly C-shaped magnetic materials such as ferrite, and are arranged in a nearly ring shape along the path of the magnetic field that is generated around the current flowing through the power cable 4 so that the magnetic field converges. The magnetic flux detector 183 is a detector that detects magnetic flux between the magnetic cores 181, 182, and for example, comprises a coil or Hall effect device. The magnetic flux detector 183 is provided inside one gap of the two gaps that are formed between the magnetic cores 181, 182, and the current value of the current flowing through the power cable 4 is measured from the magnetic flux between the gaps that are detected by the magnetic detector 183.

The power cable 4 of this fourth embodiment is a two-core cabtyre cable, and as illustrated in FIG. 10B, comprises conducting wires (cores) 41a, 41b through which electricity passes, insulation 42a, 42b that covers the conducting wires 41a, 41b, and a sheath 43 that surrounds and protects the insulation 42a, 42b.

The power cable 4 is located inside one of the two gaps that are formed between the magnetic cores 181, 182 where the magnetic flux detector 183 is not provided. Furthermore, the power cable 4 is arranged so that the conducting wire 41a of the power cable 4 is surrounded by a ring that is formed by the magnetic cores 181, 182. By arranging the power cable 4 in this way, it is possible to measure the strength of the magnetic field that occurs due to current flowing through the conducting wire 41a, while at the same time suppressing the effect of the magnetic field that occurs due to current flowing through the conducting wire 41b.

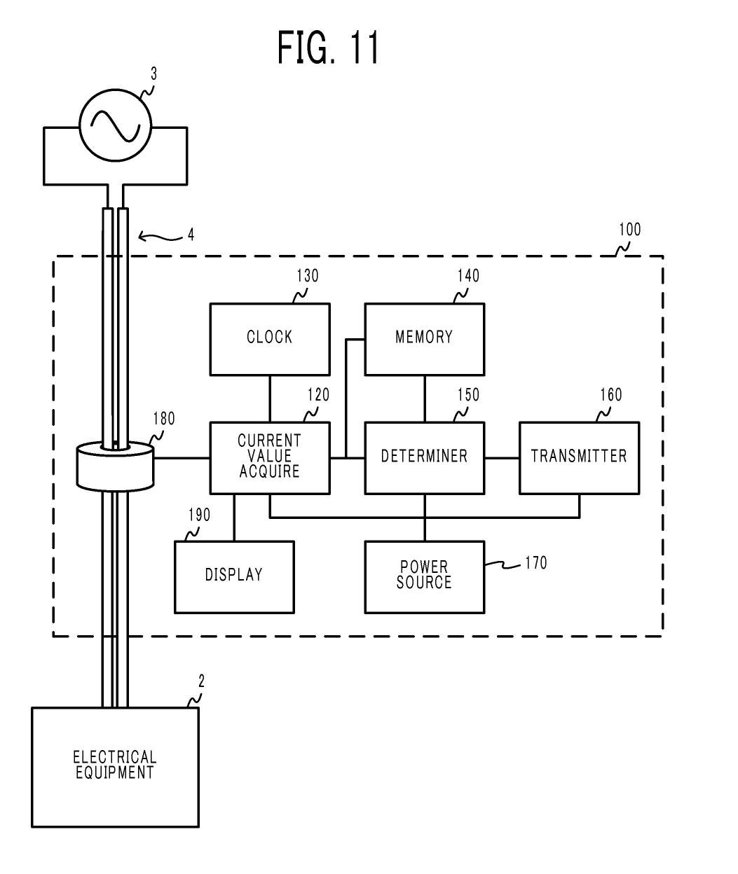

Next, the construction of the current measurement apparatus 100 of this fourth embodiment will be explained. FIG. 11 illustrates an example of the outline construction of the current measurement apparatus 100 of this fourth embodiment. As illustrated in FIG. 11, the current measurement apparatus 100 comprises a sensor 180, a current value acquirer 120, a clock 130, a memory 140, a determiner 150, a transmitter 160, a power source 170 and a display 190.

The sensor 180 is a sensor that detects the current flowing through one conducting wire 41a of the two conducting wires 41a, 41b comprised in the power cable 4, and more specifically, comprises the magnetic cores 181, 182 and the magnetic flux detector 183 as described above.

The display 190 is a display that displays the strength of the current value that is acquired by the current value acquirer 120, and for example, comprises an LED (Light Emitting Diode), the light intensity of which changes according to the strength of the current value. By providing this kind of display 190, the user is able to easily know whether or not the current measurement apparatus 100 is located in a position suitable for measuring the current flowing through the conducting wire 41a. In other words, the cabtyre cable being power cable 4 has a circular cross section, so when attaching the current measurement apparatus 100 to the power cable 4, it is difficult for the user to determine whether or not the conducting wire 41a is located inside the ring that is formed by the magnetic cores 181, 182 as illustrated in FIG. 10B. Therefore, the user easily knows, by referring the display of the display 190, when the conducting wire 41a is located inside the ring that is formed by the magnetic cores 181, 182 from the position where the strength of the current value is displayed as a maximum by the display 190, and thus it is possible to easily install the current measurement apparatus 100 in a suitable position.

With the current measurement apparatus 100 constructed as described above, as in the first embodiment, it is possible for the control apparatus 200 to acquire the operating state of the electrical equipment 2 by transmitting operation information to the control apparatus 200 based on the measured change in the current value.

### Fifth Embodiment

In the device-behavior detection system of the fourth embodiment of the technology of this disclosure, instead of common mode current as in the first embodiment, the current measurement apparatus 100 measures the current value of the current flowing through one conducting wire 41a of the current flowing through the power cable 4 that includes two conducting wires, and transmits current information to the control apparatus 200 based on the change in that current value. However, the current measurement apparatus 100, instead of the common mode current in the second embodiment described above, can also measure the current value of the current flowing through one conducting wire 41a of the current flowing through the power cable 4 that includes two conducting wires, and transmits current information to the control apparatus 200 based on the change in that current value. In other words, the current measurement apparatus 100 can also transmit current information to the control apparatus 200 when the current value in the conducting wire 41a that is detected by the sensor 180 changed. In that case as well as in the second embodiment, it is possible to acquire the operating state of the electrical equipment 2.

### Sixth Embodiment

Moreover, the current measurement apparatus 100 can also, instead of the common mode current in the third embodiment described above, measure the current value of the current flowing through one conducting wire 41a of the current flowing through the power cable 4 that includes two conducting wires, and transmit current information that indicates the measured current value to the control apparatus 200. In other words, when it is determined that the current value in the conducting wire 41a that is detected by the sensor 180 has changed, the current measurement apparatus 100 transmits current information to the control apparatus 200 that indicates the transition over time of the current value that changed. In this case as well as in the third embodiment, it is possible to acquire the operating state of the electrical equipment 2.

### Seventh Embodiment

In the sixth embodiment described above, when it is determined that the current value in the conducting wire 41a that is detected by the sensor 180 has changed, the current measurement apparatus 100 transmits current information to the control apparatus 200 indicating the transition over time of the changed current value, however, the timing at which the current information is transmitted is not limited to this. For example, the current measurement apparatus 100 can also transmit for each judgment period the transition over time of the current value of the conducting wire 41a that is detected by the sensor 180. In this case as well as in the sixth embodiment, it is possible to acquire the operating state of the electrical equipment 2.

### Eighth Embodiment

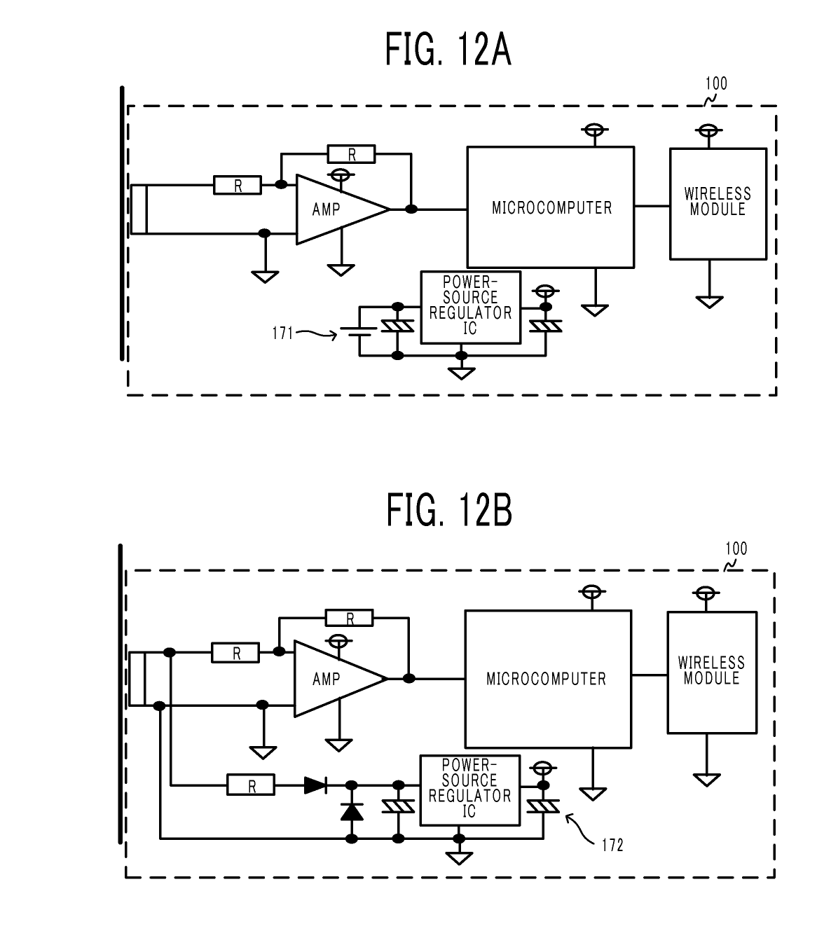

FIG. 12A and FIG. 12B illustrate examples of a circuit diagram for the current measurement apparatus 100. As illustrated in FIG. 12A, in the first through seventh embodiments described above, the power source 170 of the current measurement apparatus 100 can comprise a battery 171. Moreover, as illustrated in FIG. 12B, the power source 170 can also comprise a capacitor 172. In that case, the capacitor 172 functions as a power source 170 by part of the current that is detected by the sensor 110 being stored in the capacitor 172.

Embodiments of the technology of this disclosure are explained above, however, the technology of this disclosure is not limited by these embodiments.

For example, in the fourth through seventh embodiments above, examples of the power cable 4 being a cabtyre cable are explained, however, the type of power cable 4 is not limited to this. For example, the technology of this disclosure can also be applied to a power cable 4 that does not have a circular cross-sectional shape. In other words, the concave sections 100e, 100f of the first body 100a and the second body 100b are formed to correspond to the cross-sectional shape of the power cable 4 to which the current measurement apparatus 100 is attached.

The program that is executed in the embodiments described above can be stored and distributed on a computer-readable recording medium such as a floppy disk, CD-ROM (Compact Disk Read-Only Memory), DVD (Digital Versatile Disk), MO (Magneto Optical Disk) and the like, and a system for executing the processing described above can be created by installing that program.

Moreover, the program can be stored on a disk drive of a server on a communication network such as the Internet, and for example, can be superimposed on a carrier wave and downloaded.

When the functions described above can be achieved by the OS (Operating System), or when achieved by the OS and an application working together, only the portion other than the OS can be stored and distributed on a medium and downloaded.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

This disclosure is based on Japanese Patent Application No. 2013-088166 filed on Apr. 19, 2013, the specification, claims and drawings thereof being incorporated in this specification by reference.

### INDUSTRIAL APPLICABILITY

The technology of this disclosure is suitable for measuring current flowing through a power cable that connects electrical equipment to a power source.

### REFERENCE SIGNS LIST

1 Device-behavior detection system
100 Current measurement apparatus
100a First body
100b Second body
100c, 100d Clamp
100e, 100f Concave section
110 Sensor
120 Current value acquirer
130 Clock
140 Memory
150 Determiner
160 Transmitter
170 Power source
171 Battery
172 Capacitor
180 Sensor
181, 182 Magnetic core
183 Magnetic flux detector
190 Display
200 Control apparatus
210 Communicator
220 Input device
230 Output device
240 Memory
250 Controller
251 Current information acquirer
252 Operation information acquirer
300 Network
2 Electrical equipment
AC power source
Power cable
41a, 41b Conducting wire
42a, 42b Insulation
43 Sheath
Power outlet
Plug

1. A current measurement apparatus for measuring a current flowing through a power cable, having a plurality of conducting wires, that connects electrical equipment to a power source that supplies power to the electrical equipment, the current measurement apparatus comprising:
a first body and a second body configured to hold the power cable therebetween; and
a sensor configured to detect the current flowing through one conducting wire of the plurality of conducting wires, and provided in at least one of the first body and the second body, wherein
the sensor comprises a magnetic core configured to surround the one conducting wire as viewed from a direction of the current flowing through the plurality of conducting wires, and a magnetic flux detector configured to be disposed within a gap formed in the magnetic core.

2-3. (canceled)

4. The current measurement apparatus according to claim 1, further comprising:
a display configured to display strength of a current value that is detected by the sensor.

5. The current measurement apparatus according to claim 1, further comprising:
a determiner configured to acquire current information that indicates a change in the current value of the current that is detected by the sensor at predetermined intervals.

6. The current measurement apparatus according to claim 1, further comprising:
a determiner configured to acquire current information that indicates a change in the current value when it is determined that the amount of change in the current value of the current that is detected by the sensor is greater than a threshold value.

7. The current measurement apparatus according to claim 1, further comprising:
a determiner configured to acquire current information that indicates the transition over time of the current value when it is determined that the amount of change in the current value of the current that is detected by the sensor is greater than a threshold value.

8. A device-behavior detection system comprising a current measurement apparatus according to claim 5, and a control apparatus that is communicatively connected to the current measurement apparatus, wherein
the current measurement apparatus further comprises a transmitter configured to transmit current information that is acquired by the determiner to the control apparatus, and
the control apparatus comprises;
a current information acquirer configured to acquire current information from the current measurement apparatus; and
an operating state acquirer configured to acquire the operating state of the electrical equipment based on current information that is acquired by the current information acquirer.

9. A current measurement method executed by a current measurement apparatus for measuring a current flowing through a power cable, having a plurality of conducting wires, that connects electrical equipment to a power source that supplies power to the electrical equipment, comprising:
detecting the current flowing through one conducting wire of the plurality of conducting wires that is held between a first body and a second body of the current measurement apparatus by a sensor that is provided in at least one of the first body and the second body, wherein
the sensor comprising a magnetic core configured to surround the one conducting wire as viewed from a direction of the current flowing through the plurality of conducting wires, and a magnetic flux detector configured to be disposed within a gap formed in the magnetic core.

10. A non-transitory computer-readable recording medium storing a program for a computer for controlling a current measurement apparatus for measuring a current flowing through a power cable, having a plurality of conducting wires, that connects electrical equipment to a power source that supplies power to the electrical equipment, the program causing the computer to function as:
detection means for detecting the current flowing through one conducting wire of the plurality of conducting wires that is held between a first body and a second body of the current measurement apparatus by a sensor that is disposed in at least one of the first body and the second body, wherein
the sensor comprises a magnetic core configured to surround the one conducting wire as viewed from a direction of the current flowing through the plurality of conducting wires, and a magnetic flux detector configured to be disposed within a gap formed in the magnetic core.
